(19) United States
(12) Patent Application Publication
(10) Pub. No.: US 2005/0146325 A1
(43) Pub. Date: Jul. 7, 2005

(54) Manually operable portable magnetic field indicating device

(76) Inventor: Gideon Johannes Le Roux, Potchefstroom (ZA)

Correspondence Address: Gideon Johannes Le Roux, P O BOX 1507, POTCHEFSTROOM, 2520, ZA

(21) Appl. No.: 10/751,427

(22) Filed: Jan. 6, 2004

(51) Int. Cl. G01R 33/02; G01R 31/34

(52) U.S. Cl. 324/244; 324/800

(57) ABSTRACT

An magnetic field indicating device 10 for indicating the existence of an appropriate field of magnetism as relating to a physical or other situation comprises a metallic rod pointer 12 that is freely swivellably mounted to a handle 14. The section 12.1 of the pointer 12 is journalled to the handle 14 and fitted with a metallic slider 18 that fits resistably slidably thereto to permit its desirable manual positioning there along. The top end of the handle 14 presents a protractor carrying face 20. The device 10 carries a compass 26 and a spirit level 28 as mounted to the face 20. The handle 14 is fitted with restraining means for frictionally restraining displacement of the pointer 12 about its pivotal axis. When in use the device 10 is held to cause the pointing section 12.2 to extend generally horizontally.

### CROSS REFERENCE TO RELATED APPLICATIONS

Not applicable

### BACKGROUND TO THE INVENTION

The invention of this application relates to the field of establishing the existence of magnetic or other fields as relating to physical or other situations such as the assessment of geological phenomena for example in searching for water or even surrounding a being.

A variety of types of equipment is used in assessing geological phenomena associated with the existence of an environmental magnetic field; from very complicated to the ordinary manually operable dowsing device. In this regard the applicant has previously obtained patent protection in South Africa for a dowsing device that uses the principle of the existence of an environmental magnetic field being indicative of underground water. The applicant has by trial and error empirically found that his previous invention has yielded positive results in so indicating underground water. It will be appreciated that equipment used for such purpose does not give an infallible result but only serves as indication of the existence of such water.

### BRIEF SUMMARY OF THE INVENTION

The present invention is an improvement to the applicant's first patent. While the approach used is in essence the same as that of the previous patent the applicant has found that the introduction of previously unrealised improvements has significantly broadened the scope of application of the invention in that it can be used to assess the existence of magnetic fields of a variety of strengths relating to circumstances not limited to the finding of underground water only and also to aiding in drawing the attention of a user to a find. The use of the invention in other circumstances as only as dowsing device requires empirical assessment that, once established, can be used to indicate the existence of magnetic fields relating to such other circumstances. It is, however, stressed that the invention does not claim to give highly infallible results but is useful in at least being indicative of the existence of a magnetic or other field relating to a physical or even other phenomenon.

### BRIEF DESCRIPTION OF THE DRAWING

FIG. 1 shows a plan view one embodiment of a manually operable portable magnetic field indicating device,

FIG. 2 shows the embodiment of FIG. 1 in side elevation,

FIG. 3 shows in side elevation another embodiment of an indicating device as incorporating equipment to aid in drawing the attention of a user to a find,

FIG. 4 shows the FIG. 3 embodiment in plan view, and

FIG. 5 shows electric circuitry associated with the FIGS. 3 and 4 embodiment of the invention.

### DETAILED DESCRIPTION OF THE INVENTION

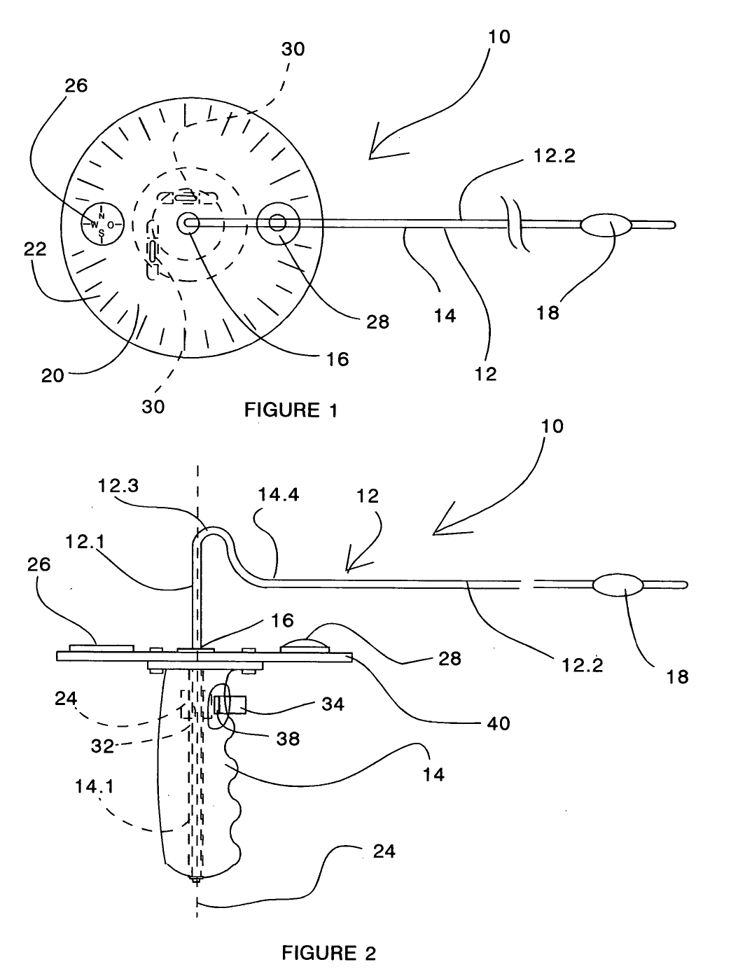

FIGS. 1 and 2—One Embodiment of the Invention

Referring to FIGS. 1 and 2 of the drawings a magnetic field indicating device for indicating the existence of an appropriate field of magnetism or other field as relating to a physical or other situation that creates observable magnetic activity such as the existence of underground water is generally indicated by reference numeral 10. The device 10 of this embodiment is thus in the form of a dowsing device.

The device 10 comprises a metallic rod pointer 12 that is freely swivellably mounted to a handle 14 owing to the pointer 12 being formed with an inner end section 12.1 that is journalled to a bore 14.1 in the handle 14 and a rectilinearly extending pointing section 12.2 that extends radially from the inner end section 12.1. The transition between the section 12.1 and the pointing section 12.2 extends though a bow 12.3 that promotes the flexibility of the pointing section 12.2. The section 12.1 is journalled to the handle 14 while the pointer 12 is prevented from dropping into the bore 14.1 to the extent of limiting its free swivellability, once in use, by way of a thrust flange 16 that bears on the area surrounding the entrance to the bore 14.1. The pointer 12 fits freely removably to the handle 14. When in use the device 10 is held to cause the pointing section 12.2 to extend generally horizontally.

The pointing section 12.2 is fitted with a metallic slider 18 that manually displaceably though against free sliding fits the section 12.2 to permit its desirable manual positioning along the section 12.2 during use of the device 10. The slider 18 can be of a single metal or of bimetallic or even multi-metallic composition. It can also be of the same metal as the pointer 12. As an example the pointer 12 can be of brass while the slider 18 is also of brass or of, for example, of lead.

The slider 18 is used to adapt the device 10 for use in a variety of circumstances. When a field of magnetism is desired to picked up over a longer distance the slider 18 will, for example, be positioned towards the leading end of the section 12.2 while a search for a nearer field will require positioning of the slider 18 towards the root 12.4 of the section 12.2.

The top end of the handle 14 is fitted to present a protractor carrying face 20. The axis of the protractor 22, as presented by the face 20, is co-incidental with the axis of swivelling 24 of the pointer 14. The protractor 22 presents markings extending through either 360 degrees or 180 degrees.

The device 10 also carries a compass 26 and a spirit level 28, as mounted on the face protractor 22. As shown in FIG. 1, in stead of a single spirit level 28, a pair of spirit levels 30 (shown in broken lines) arranged at right angles to one another can be used.

Referring particularly to FIG. 2, the handle 14 is fitted with restraining means for frictionally restraining displacement of the pointer 12 about its pivotal axis. This is provided by the section 12.1 being formed with a thickened portion 32 having a round cylindrical outer surface internally of the handle 14. Adjacent the position of the thickened portion 32 the handle 14 is mounted with an outwardly protruding and biased trigger-like button 34 that is provided internally with a pad of friction material 38 adapted to engage with the cylindrical surface of the thickened portion 32 for frictionally restraining the pivotal displacement of the pointer 14.

The protractor carrying face 20 of the FIGS. 1 and 2 embodiment of the invention is presented by a disk 40 mounted at the upper end of the handle 14.

Use of the FIGS. 1 and 2 embodiment of the invention involves a person holding a device 10 or a device 10 in each hand with the zero on the protractor 22 facing directly ahead. The spirit level 28, or the pair of spirit levels 30, is/are used to ensure that the pivotal axis of the pointer 12 is maintained in a horizontal attitude. The movement of the pointing sections 12.2 of the pointer 12 of each of the devices 10 under chosen circumstances is indicative of the existence and/or direction of a field of magnetism. When used as a dowsing device the pointers 12 of the respective devices 10 will move from randomly pivotable to a specific position relative to one another when picking up the magnetic field of an underground source of water while a person holding the devices walks along land. The compasses 26 can be involved to locate the source of water. Free pivotal displacement of the pointer 12 is restrainable by the trigger-like button 34. It is thus used to lock the pointer 12 of the or each device 12 once a magnetic field has been registered to assist in establishing its whereabouts.

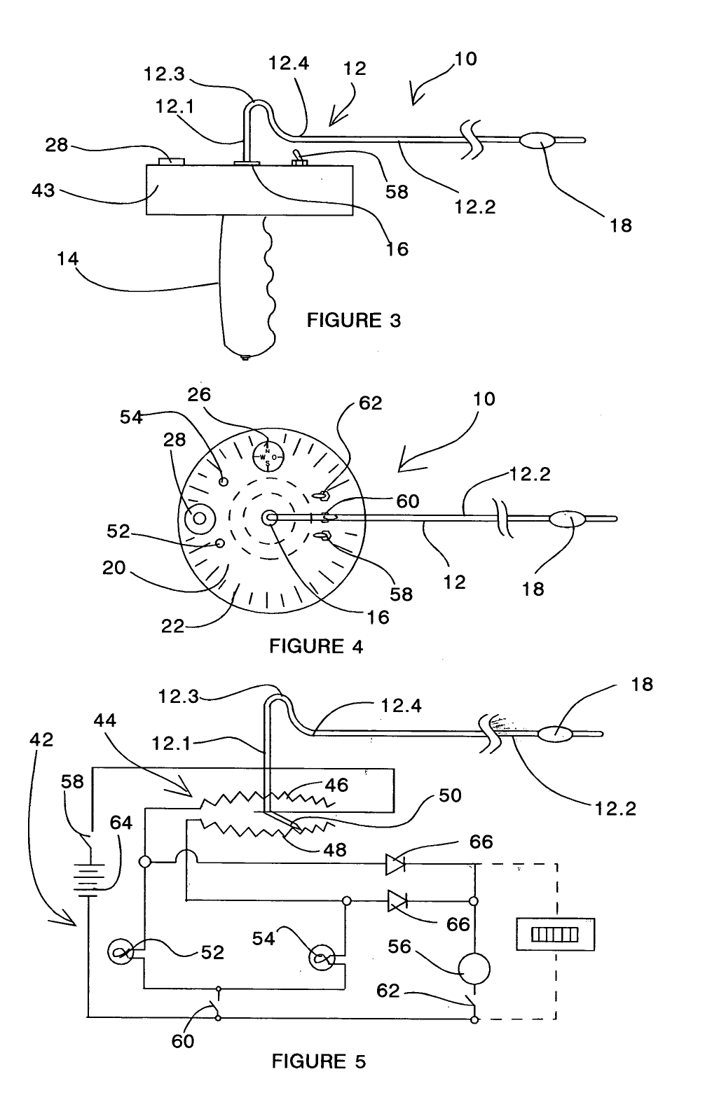

FIGS. 3 to 5—A Further Embodiment of the Invention

While the FIGS. 3 to 5 embodiment is a further development of the FIGS. 1 and 2 embodiment, like parts carry the same reference numbers.

The device 10 of the FIGS. 3 to 5 embodiment includes sensing means in the form of electric circuitry generally indicated by reference numeral 42 mainly fitted to a housing 43 and incorporating a rheostat 44 presenting two resistive elements 46 and 48 over which a wiper arm 50, that is mounted to move in unison with the pointer 12, is movable in current flow contact with the elements 46, 48 respectively. The overhead portion of the housing 43 presents the protractor carrying face 20. The circuitry 42 also includes indicating means in the form of two lamps 52 and 54 displayed on the protractor carrying face 20, and a buzzer 56. To activate the desired part of the circuitry 42 it is fitted with three on/off type switches 58, 60 and 62 also provided on the protractor carrying face 20. The circuitry 42 incorporates a source of power in the form of a dry cell battery 64. One pole of the battery 64 is electrically connected via the switch 58 to the wiper arm 50. One end of the element 46 is connected via the lamp 52 to one terminal of the switch 60 of which the other terminal is connected to the other pole of the battery 64. Likewise the one end of the element 48 is connected via the lamp 54 to the corresponding terminal of the switch 60. The ends of the resistance elements 46 and 48 that are in contact with the one terminal of the switch 60 are each also connected via a diode 66 to the one terminal of a buzzer 56 the other terminal of which is connected via the switch 62 to the other pole of the battery 64. The slider 18 of this embodiment can also be permanently fixed to the outer end of the pointer 12.

Use of this embodiment of the invention also involves a person holding one device 10 or a device 10 in each hand. The spirit level 28 is again used to ensure that the pivotal axis of the pointer 12 is maintained in a vertical attitude. Similar to the FIGS. 1 and 2 embodiment, the movement of the pointing sections 12.2 of the pointer 12 of each of the devices 10 under chosen circumstances is indicative of the existence or direction of a field of magnetism as moving from randomly pivotable to specific positions.

When the switches 58, 60 and 62 are in their on positions the lamps 52 and 54 and the buzzer 68 will provide an additional indication of the movement of the pointer(s) 12. For as long as the arm 50 does not make contact with either element 46 or 48 the lamps 52 or 54 will not illuminate. When so using a device 10 the pointer 12 will be maintained in its neutral and straight ahead condition when still randomly pivotable. Once the pointer(s) 12 comes under the action of a magnetic force it will become deflected to the appropriate side with the arm 50 making appropriate electrical contact with the relevant element 46 or 48 causing the energisation of the related lamp 52 or 54. Owing to the rheostat effect of the elements 46 and 48 the intensity of the illumination will increase with the extent of the angle of deflection of the pointer 12 from its neutral condition. The buzzer 56 will act in co-operation with the lamps 52 and 54, whichever one becomes activated, resulting in a more intense sound reflecting the extent of displacement of the pointer 12 from its neutral and thus straight ahead condition. The lamp 52, 54 becoming illuminated will show the direction of the source of the magnetic effect while its intensity, as coupled with the intensity of the sound of the buzzer 56, will relate to the extent of deflection of the pointer 12 from the neutral condition that, at least in the case of using the device 10 as dowsing device, will be indicative of the location of the underground source of water.

If so desired the device 10 can incorporate a read out facility 70 that numerically reflects the angle of deflection.

The device 10 in either embodiment can be thus be used to search for situations that is reflected by a field of magnetism such as for geological faults, underground water, minerals, and other situations.

While not yet scientifically provable the inventor has empirically found that the device can even be used to measure fields surrounding a being relating to psychological characteristics such as temperament. It is presently assumed that such field is of magnetic or electromagnetic character. The field reflecting such is thus picked by the device 10 at various positions relative to such person as correlating with various types of temperaments.

1) a portable and manually operable magnetic or other field indicating device for indicating the existence of a field of magnetism or other field at least perceived by the device, once in use, to be generally static comprising
at least one metallic rod pointer that is mounted to be at least partly circumferentially freely pivotable about while extending at least substantially radially with respect to an axis of swivelling that, in turn, extends along a handle to which the pointer is pivotally mounted, at least once the device is ready for use enabling the circumferentially free swivellable displacement of the pointer relative to the handle to the extent permitted, and
a metallic slider, not necessarily being of the same metal as the pointer, that manually displaceably though against free sliding fits the rod pointer and that is used to accommodate the measurement of a variety of magnetic field situations within the ability of the device even if requiring establishing it by trial and error,
the device when operatively used once the slider has been appropriately positioned, being held with the axis of swivelling extending at least substantially upright resulting in the pointer being displaceable in an at least substantially horizontal plane with the pointer taking in a specific stance, in the appropriate case becoming displaced thereto, once an appropriate magnetic field is perceived by the device.

2) A device as claimed in claim 1 that is fitted with a protractor that is suitably situated with respect to the pointer to cause it to be swivelled over the graduations of the protractor, whereby the position of the pointer relative to the graduations, as being indicative of a characteristic of a magnetic field, is thus establishable.

3) A device as claimed in claim 1 or claim 2 that includes a spirit level arranged to indicate the verticality of the axis of swivelling of the pointer once the device is in use.

4) A device as claimed in any one of the preceding claims that includes a compass by means of which the attitude of the device relative to the earth's magnetic north is determinable.

5) A device as claimed in any one of the preceding claims in which the metallic slider is of at least bi- if not multi-metallic composition.

6) A device as claimed in any one of the preceding claims that includes restraining means for frictionally restraining displacement of the pointer about its pivotal axis that is at least employable to lock the pointer in a specific position once in use.

7) A device as claimed in claim 6 in which the restraining means is adjustable to adjust the restraining action thereof.

8) A device as claimed in any one of the preceding claims in which the pointer is formed with an inner end section that extends at least substantially transverse with its rectilinearly and radially extending pointing section with the inner end section thus extending along the axis of swivelling of the pointer and about which the pointing section is radially displaceable.

9) A device as claimed in claim 8 in which the inner end section of the pointer is journalled in a bore in the handle.

10) A device as claimed in claim 10 in which the transition between the radially extending pointing section and the inner end section of the pointer extends though a bow thereby promoting the flexibility of the radially extending pointing section.

11) A device as claimed in any one of the preceding claims that includes sensing means for sensorially perceiving the angular position of the rod relative to the handle and indicating means, tying in with the sensing means, to provide an indication of the position of the arm relative to the handle.

12) A device as claimed in claim 11 in which the sensing means is arranged to provide an output in the form of an electric signal corresponding with the position of the arm relative to the handle.

13) A device as claimed in claim 12 in which the sensing means is in the form of a rheostat incorporating a resistance element and a wiper arm co-operating sweeping fashion with the resistance element while being connected to move in unison with the swivelling action of the pointer, the rheostat being suitably serially interspaced along the circuitry to cause the extent of the flow of current via the indicating means, as also electrically activatable and forming part of the circuitry once the circuitry is activated from a constant source of electrical power forming part of the circuitry, as being dependent on the extent of swivelling of the pointer, to be reflected in the perceivable output from the indicating means.

14) A device as claimed in any one of claims 11 to 13 in which the indicating means is in the form of at least one of an electric lamp, acoustic signalling means and a digital display, the latter being arranged to give a digital indication of the angular position of the pointer arm.

15) A device as claimed in any one of the preceding claims that incorporates measuring means for measuring its elevation above a basis along which it is used.
